(19) United States
(12) Patent Application Publication
(10) Pub. No.: US 2012/0031493 A1
(43) Pub. Date: Feb. 9, 2012

(54) TANDEM ORGANIC SOLAR CELL USING A POLYELECTROLYTE LAYER, AND METHOD FOR MANUFACTURING THE SAME

(75) Inventors: Kwanghee Lee, Gwangju (KR); Byoung Hoon Lee, Gwangju (KR); Sung Heum Park, Gwangju (KR); Sun-Hee Kim, Gwangju (KR)

(73) Assignee: GWANGJU INSTITUTE OF SCIENCE AND TECHNOLOGY, Buk-gu, Gwangju (KR)

(21) Appl. No.: 13/264,279

(22) PCT Filed: Apr. 13, 2010
(86) PCT No.: PCT/KR2010/002251

§ 371 Date: Oct. 13, 2011

(30) Foreign Application Priority Data
Apr. 13, 2009 (KR) 10-2009-0031659

(51) Int. Cl. H01L 51/46; H01L 51/44; H01L 51/48

(52) U.S. Cl. 136/263; 438/82; 257/E51.024

(57) ABSTRACT

The invention relates to a tandem organic solar cell using a polyelectrolyte layer and a method for manufacturing same. The tandem organic solar cell comprises a first electrode, a first organic photoactive layer, a recombination layer, a second organic photoactive layer, and a second electrode. The recombination layer includes an n-type semiconductor material layer and a conjugated polyelectrolyte layer.

### CROSS-REFERENCE TO RELATED APPLICATIONS

This application claims the benefit under 35 U.S.A. §119 of Korean Patent Application No. 10-2009-0031659 filed on Apr. 13, 2009 in the Korean Intellectual Property Office and International Application No. PCT/KR2010/002251, filed on Apr. 13, 2010, the entireties of which are incorporated herein by reference.

### TECHNICAL FIELD

The present invention relates to solar cells and, more particularly, to organic solar cells.

### BACKGROUND ART

Organic solar cells have been a center of attention as alternative energy sources due to high oil prices, and various studies have been conducted to develop organic solar cells capable of decreasing manufacturing costs while securing various inherent merits of organic solar cells including flexibility. Particularly, overcoming low power conversion efficiency through introduction of a tandem device structure together with development of new materials for the organic solar cells has been studied.

However, most conventional tandem organic solar cells are small molecule-based tandem organic solar cells which require a high-vacuum deposition process. Moreover, even when forming a polymer photoactive layer through a solution process, post heat treatment is required for the purpose of improving efficiency, thereby making it difficult to apply heat-vulnerable conjugated polymers to the photoactive layer.

### DISCLOSURE

### Technical Problem

The present invention is directed to providing organic solar cells that exhibit superior characteristics without heat treatment, releasing limitation in selection of polymers for a photoactive layer of the organic solar cell.

### Technical Solution

In accordance with one aspect of the invention, a tandem organic solar cell is provided. The tandem organic solar cell includes a first electrode, a first organic photoactive layer, a recombination layer, a second organic photoactive layer, and a second electrode. The recombination layer includes an n-type semiconductor material layer and a conjugated polyelectrolyte layer.

In accordance with another aspect of the invention, a tandem organic solar cell is provided. The tandem organic solar cell includes a first electrode and a first organic photoactive layer formed on the first electrode. A recombination layer is formed on the first organic photoactive layer, and includes an n-type semiconductor material layer and a conjugated polyelectrolyte layer sequentially formed on the first organic photoactive layer. A second organic photoactive layer is formed on the recombination layer. A second electrode is formed on the second organic photoactive layer.

In accordance with a further aspect of the invention, a tandem organic solar cell is provided. The tandem organic solar cell includes a first electrode and a first organic photoactive layer formed on the first electrode. A recombination layer is formed on the first organic photoactive layer, and includes a conjugated polyelectrolyte layer and an n-type semiconductor material layer sequentially formed on the first organic photoactive layer. A second organic photoactive layer is formed on the recombination layer. A second electrode is formed on the second organic photoactive layer.

In accordance with yet another aspect of the invention, a method for manufacturing a tandem organic solar cell is provided. First, a first electrode is formed. A first organic photoactive layer is formed on the first electrode. A recombination layer including an n-type semiconductor material layer and a conjugated polyelectrolyte layer is formed on the first organic photoactive layer. A second organic photoactive layer is formed on the recombination layer. A second electrode is formed on the second organic photoactive layer.

### Advantageous Effect

Organic solar cells according to exemplary embodiments of the invention may have improved open circuit voltage through a room temperature process, by which the open circuit voltage is increased to the sum of open circuit voltages of two or more single organic solar cells. Considering that efficiency of a solar cell is directly proportional to open circuit voltage, this effect shows that efficiency of the organic solar cell may be maximized by a tandem structure of the organic solar cell through a room temperature process. In other words, the organic solar cells according to the exemplary embodiments are distinguished from conventional tandem organic solar cells, which are subjected to a solution process and heat treatment at high temperature to improve open circuit voltage after manufacture of cell elements. This means that the organic solar cells according to the exemplary embodiments may eliminate high temperature heat treatment, simplify the manufacturing process, and widen the range of selection for photoactive materials to heat-vulnerable photoactive materials with excellent characteristics, thereby providing maximized efficiency of the organic solar cells.

Further, according to the exemplary embodiments, the organic solar cell permits variation in intensity of electric fields within a polyelectrolyte layer through movement of ions in a conjugated polyelectrolyte layer to facilitate movement of charges in the photoactive layer, so that the conjugated polyelectrolyte layer may act as a charge transport layer. Accordingly, limitation to an energy level of materials for the conjugated polyelectrolyte layer and the photoactive layer may be relieved, and recombination of electrons and holes may further actively occur between an n-type semiconductor material layer and the conjugated polyelectrolyte layer due to a high HOMO level of the n-type semiconductor material layer and a low LUMO level of the conjugated polyelectrolyte layer.

### DESCRIPTION OF DRAWINGS

The above and other aspects, features, and advantages of the invention will become apparent from the detailed description of the following embodiments in conjunction with the accompanying drawings:

FIG. 1 is a schematic view of a tandem organic solar cell 100 according to one exemplary embodiment of the present invention;

FIG. 2 is an energy diagram of one example of the tandem organic solar cell of FIG. 1;

FIG. 3 is a schematic view of a tandem organic solar cell 200 according to one exemplary embodiment of the present invention;

FIG. 4 is an energy diagram of one example of the tandem organic solar cell of FIG. 3; and

FIG. 5 is a graph depicting current density with respect to voltage of tandem organic solar cells prepared in Example 1 and Comparative Example 2.

### BEST MODE

The present invention may be embodied in different ways and exemplary embodiments will be described in detail with reference to the accompanying drawings. However, it should be understood that the present invention is not limited to the embodiments disclosed herein and include all modifications, equivalents and alternates within the scope and spirit of the present invention. Like components will be denoted by like reference numerals throughout the accompanying drawings.

Exemplary embodiments of the invention will now be described in detail with reference to the accompanying drawings.

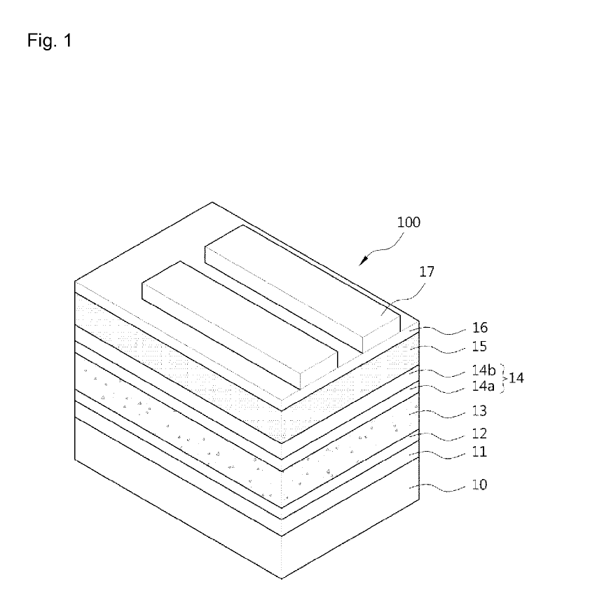

FIG. 1 is a schematic view of a tandem organic solar cell 100 according to one exemplary embodiment of the present invention.

Referring to FIG. 1, a first electrode 11, a first charge transport layer 12, a first organic photoactive layer 13, a recombination layer 14, a second organic photoactive layer 15, a second charge transport layer 16 and a second electrode 17 may be sequentially formed on a substrate 10. The first charge transport layer 12 and/or the second charge transport layer 16 may be omitted.

The substrate 10 may be a light transmitting layer. The light transmitting layer may be a glass or plastic substrate. The first electrode 11 may be a light transmitting electrode. The first electrode 11 may be an indium tin oxide (ITO) layer, a fluorinated tin oxide (FTO) layer, an indium zinc oxide (IZO) layer, an Al-doped zinc oxide (AZO) layer or an indium zinc tin oxide (IZTO) layer.

The first charge transport layer 12 may be a hole transport layer for facilitating transport of holes generated in the first photoactive layer 13 to the first electrode 11. In addition, the first charge transport layer 12 may act as a buffer layer which relieves surface roughness of the first electrode 11. One example of the first charge transport layer 12 includes a layer which contains PEDOT:PSS (poly(3,4-ethylenedioxythiophene):poly(styrenesulfonate)) or conjugated polyelectrolyte described below.

The first organic photoactive layer 13 and the second organic photoactive layer 15 generate electron-hole pairs, that is, excitons, through absorption of light, and may include an electron donor material and an electron acceptor material. The organic photoactive layers 13, 15 may be bulk heterojunction (BHJ) layers in which the electron donor material and the electron acceptor material are blended with each other. Alternatively, in the organic photoactive layers 13, 15, the electron donor material and the electron acceptor material may be sequentially stacked.

The electron donor material excites electrons from an energy level of the HOMO (Highest Occupied Molecular Orbital) to an energy level of the LUMO (Lowest Unoccupied Molecular Orbital) through absorption of light. Examples of electron donor materials may include polythiophenes, polyfluorene, polyanilines, polycarbazoles, polyvinylcarbazoles, polyphenylenes, polyphenylvinylenes, polysilanes, polythienylenevinylenes, polyisothianaphthanenes, polycyclopentadithiophenes, polysilacyclopentadithiophenes, polycyclopentadithiazoles, polythiazolothiazoles, polythiazoles, polybenzothiadiazoles, poly(thiophene oxide)s, poly(cyclopentadithiophene oxide)s, polythiadiazoloquinoxaline, polybenzoisothiazole, polybenzothiazole, polythienothiophene, poly(thienothiophene oxide), polydithienothiophene, poly(dithienothiophene oxide)s, polytetrahydroisoindoles, or copolymers thereof. In one exemplary embodiment, the electron donor material may be poly(3-hexylthiophene; P3HT) which is one form of polythiophene, or poly(cyclopentadithiophene-co-benzothiadiazole) which is one kind of polycyclopentadithiophenes. Poly(cyclopentadithiophene-co-benzothiadiazole) may be PCPDTBT (poly[2,6-(4,4-bis-(2-ethylhexyl)-4H-cyclopenta[2,1-b;3,4-b′]dithiophene)-alt-4,7-(2,1,3-benzothiadiazole)]).

The electron acceptor material accepts electrons excited from the electron donor material, and may be C60 to C84 fullerenes or derivatives thereof, such as C60, C70, C76 and C84 fullerenes and derivatives thereof; perylene; polymers; or quantum dots. One example of the fullerene derivatives includes PCBM(C60)([6,6]-phenyl-C61-butyric acid methyl ester) or PCBM(C70)([6,6]-phenyl-C71-butyric acid methyl ester) as examples of PCBM.

Each of the first and second organic photoactive layers 13, 15 may independently include one of the electron donor materials described above and one of the electron acceptor materials described above.

Each of the organic photoactive layers 13, 15 may be formed by dissolving a selected electron donor material and a selected electron acceptor material in a solvent, followed by a solution process. The solvent may be an organic solvent, such as chlorobenzene, dichlorobenzene, chloroform, toluene, tetrahydrofuran, xylene, or the like. If the organic photoactive layers 13, 15 are bulk-hetero-junction layers, the donor material and the acceptor material may be mixed in a ratio of 1:0.1 to 1:10 in terms of weight. The solution process may be spin coating, ink-jet printing, doctor blade coating, electro-spraying, dip coating or screen printing.

In the recombination layer 14, electrons generated in the first organic photoactive layer 13 and holes generated in the second organic photoactive layer 15 recombine each other. The recombination layer 14 may include an n-type semiconductor material layer 14a near the first organic photoactive layer 13 and a conjugated polyelectrolyte layer 14b near the second organic photoactive layer 15.

The n-type semiconductor material layer 14a facilitates inflow of the electrons from the first organic photoactive layer 13 but suppresses inflow of the holes therefrom. In the n-type semiconductor material layer 14a, an energy level of the LUMO (Lowest Unoccupied Molecular Orbital) or the conduction band may be higher than that of the LUMO in the first organic photoactive layer 13 (in view of vacuum level), and an energy level of the HOMO (Highest Occupied Molecular Orbital) or the valence band may be higher than that of the HOMO in the first organic photoactive layer 13 (in view of vacuum level). The n-type semiconductor material layer 14a may be a metal oxide layer. The metal oxide may be titanium oxide, zinc oxide, tungsten oxide, vanadium oxide, molybdenum oxide, or combinations thereof.

The conjugated polyelectrolyte layer 14b includes a conjugated polymer having side chain charges and counter ions having charges opposite the charges of the conjugated polymer to exhibit electrolyte characteristics. The conjugated polyelectrolyte layer 14b, particularly, the main chain of the polyelectrolyte, may have a lower LUMO energy level than that of the second organic photoactive layer 15 (in view of energy level under vacuum). Consequently, the conjugated polyelectrolyte layer 14b is capable of suppressing inflow of the electrons from the second organic photoactive layer 15. On the other hand, an electric field of part near the conjugated polyelectrolyte layer 14b becomes different from the electric field of the overall cell elements through movement of ions in the conjugated polyelectrolyte layer 14b, thereby allowing the holes in the second organic photoactive layer 15 to be easily transferred to the conjugated polyelectrolyte layer 14b by increased intensity of the electric field. In this case, limitation to the energy level of the HOMO in the conjugated polyelectrolyte layer 14b may be relieved.

The LUMO of the conjugated polyelectrolyte layer 14b has a lower energy level than the LUMO of the n-type semiconductor material layer 14a (in view of vacuum level), so that the electrons introduced into the n-type semiconductor material layer 14a are blocked by the energy level of the LUMO in the conjugated polyelectrolyte layer 14b and thus cannot drift to thereto. Further, since the HOMO of the n-type semiconductor material layer 14a has a higher energy level than the HOMO of the conjugated polyelectrolyte layer 14b (in view of energy level under vacuum), the holes introduced into the conjugated polyelectrolyte layer 14b are blocked by the energy level of the HOMO in the n-type semiconductor material layer 14a and thus cannot drift to thereto. Therefore, the holes and the electrons may recombine each other at an interface between the n-type semiconductor material layer 14a and the conjugated polyelectrolyte layer 14b.

Such a conjugated polyelectrolyte layer 14b may contain at least one selected from the group consisting of poly(9,9-bis(6″-(N,N,N-trimethylammonium)hexyl)fluorene-alt-co-phenylene), poly((2-cyclooctatetraenylethyl)-trimethylammonium trifluoromethanesulfonate), poly-(tetramethylammonium-2-cyclooctatetraenylethanesulfonate), poly((2-methoxy-5-(3-sulfonatopropoxy)-1,4-phenylene)-1,2-ethenediyl), poly((2-methoxy-5-propyloxysulfonate-1,4-phenylenevinylene)-alt-(1,4-phenylenevinylene)), sulfonated poly(p-phenylene), sulfonated poly(phenylene ethynylene), poly(carboxylatedphenylene ethynylene), poly(N-(4-sulfonatobutyloxyphenyl)-4,4′-diphenylamine-alt-1,4-phenylene), poly(N-4,4′-diphenylamine-alt-N-(p-trifluoromethyl)phenyl-4,4′-diphenylamine), poly((9,9-bis(6′-(N,N,N-trimethylammonium)hexyl)-fluorene-2,7-diyl)-alt-(2,5-bis(pphenylene)-1,3,4-oxadiazole)), poly((9,9-bis(6′-N,N,N-trimethylammoniumbromide)hexyl)fluorene-co-alt-4,7-(2,1,3-benzothiadiazole)), and PFP(poly(9,9′-bis(4-sulfonatobutyl)fluorene-alt-co-1,4-phenylene)). Additionally, the conjugated polyelectrolyte layer 14b may include H, Na, K or tetradecyltrimethylammonium (TDMA) as counter cations, or Br, BF₄, CF₃SO₃, PF6, BPh₄, and B(3,5-(CF₃)₂C₆H₃)₄(BArF₄) as counter anions.

In one example, the conjugated polyelectrolyte layer 14b may be PFP-Na represented by Formula 1:

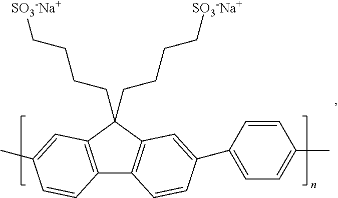

where n may be an integer in the range from 10 to 100000.

The second charge transport layer 16 may act as an electron transport layer which facilitates transport of electrons from the second organic photoactive layer 15 to the second electrode 17. Additionally, the second charge transport layer 16 may act as a hole suppression layer that suppresses transport of holes from the second organic photoactive layer 15 to the second electrode 17. The second charge transport layer 16 may be a titanium (Ti) oxide layer. The titanium oxide layer may prevent degradation of the cell caused by intrusion of oxygen or vapor into the organic photoactive layers 13, 15. Further, the titanium oxide layer may act as an optical spacer for increasing the amount of light introduced into the organic photoactive layers 13, 15 and as a lifespan increasing layer for increasing the lifespan of the organic cell. The titanium oxide layer may be formed by a sol-gel process and may have a thickness of 2 to 50 nm.

The second electrode 17 has a lower work function than the first electrode (in view of energy level under vacuum), and may be a metal or conductive polymer electrode. In one example, the second electrode 17 may be an Al layer, a Ca layer, or an Mg layer. Preferably, the second electrode 17 may be an Al layer which has a low work function and is stable in air. The second electrode 17 may be formed by thermal evaporation, e-beam evaporation, RF (Radio Frequency) sputtering or magnetron sputtering, without being limited thereto.

The tandem organic solar cell according to this embodiment may be subjected to heat treatment. The heat treatment may be performed at 80° C. to 200° C., preferably 150° C.

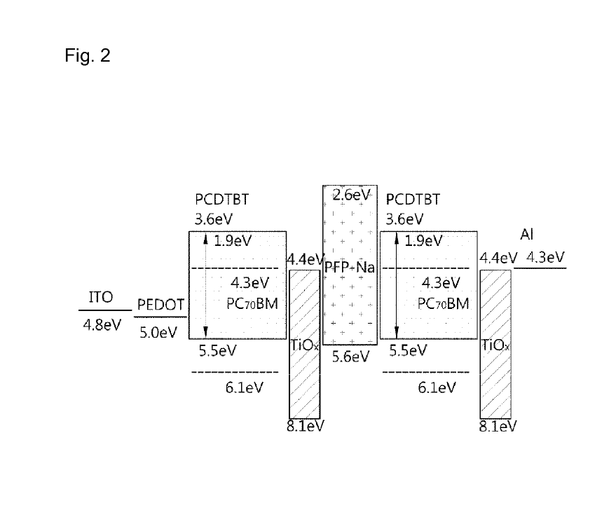

FIG. 2 is an energy diagram of one example of the tandem organic solar cell of FIG. 1. Specifically, the first electrode 11 (in FIG. 1) is an ITO layer and the first charge transport layer 12 (in FIG. 1) is a PEDOT:PSS layer. Each of the first and second organic photoactive layers 13, 15 (in FIG. 1) is a PCDTBT:PC₇₀BM layer and the recombination layer 14 (in FIG. 1) includes a TiOx layer and a PFP-Na layer sequentially stacked on the first organic photoactive layer 13 (in FIG. 1). The second charge transport layer 16 (in FIG. 1) is a TiOx layer and the second electrode 17 (in FIG. 1) is an Al layer.

Referring to FIG. 2, the conduction band of the n-type semiconductor material layer (titanium oxide layer) has an energy level of 4.4 eV, which is greater than an energy level of 4.3 eV of the LUMO of PC70BM used as the electron acceptor material and an energy level of 3.6 eV of the LUMO of PCDTBT used as the electron donor material in the first organic photoactive layer (PCDTBT:PC₇₀BM). Further, the valence band of the of the n-type semiconductor material layer (titanium oxide layer) has an energy level of 8.1 eV, which is greater than an energy level of 5.5 eV of the HOMO of PCDTBT used as the electron donor material in the first organic photoactive layer (PCDTBT:PC₇₀BM). Accordingly, the n-type semiconductor material layer (titanium oxide layer) may facilitate inflow of electrons from the first organic photoactive layer (PCDTBT:PC₇₀BM) while suppressing inflow of holes therefrom.

On other hand, the LUMO of the conjugated polyelectrolyte layer (PFP-Na layer) has an energy level of 2.6 eV, which is greater than an energy level of 4.3 eV of the LUMO of PC₇₀BM used as the electron acceptor material and an energy level of 3.6 eV of the LUMO of PCDTBT used as the electron donor material in the second organic photoactive layer (PCDTBT:PC₇₀BM). As a result, the conjugated polyelectrolyte layer may suppress inflow of electrons from the second organic photoactive layer (PCDTBT:PC₇₀BM). On the other hand, the HOMO of the conjugated polyelectrolyte layer (PFP-Na layer) has an energy level of 5.6 eV, which is greater than an energy level of 5.5 eV of the HOMO of PCDTBT used as the electron donor material in the second organic photoactive layer (PCDTBT:PC₇₀BM). Accordingly, although the conjugated polyelectrolyte layer may not allow efficient inflow of holes from the second organic photoactive layer (PCDTBT:PC₇₀BM), variation in electric field through rearrangement of ions in the conjugated polyelectrolyte layer (PFP-Na layer) may result in efficient inflow of the holes therefrom.

Further, the electrons introduced into the n-type semiconductor material layer (titanium oxide layer) are blocked by the energy level of the LUMO in the conjugated polyelectrolyte layer (PFP-Na layer) and thus cannot drift to thereto. The holes introduced into the conjugated polyelectrolyte layer (PFP-Na layer) are blocked by the energy level of the HOMO in the n-type semiconductor material layer (titanium oxide layer) and thus cannot drift to thereto. As a result, the holes and the electrons may recombine each other at an interface between the n-type semiconductor material layer (titanium oxide layer) and the conjugated polyelectrolyte layer (PFP-Na layer).

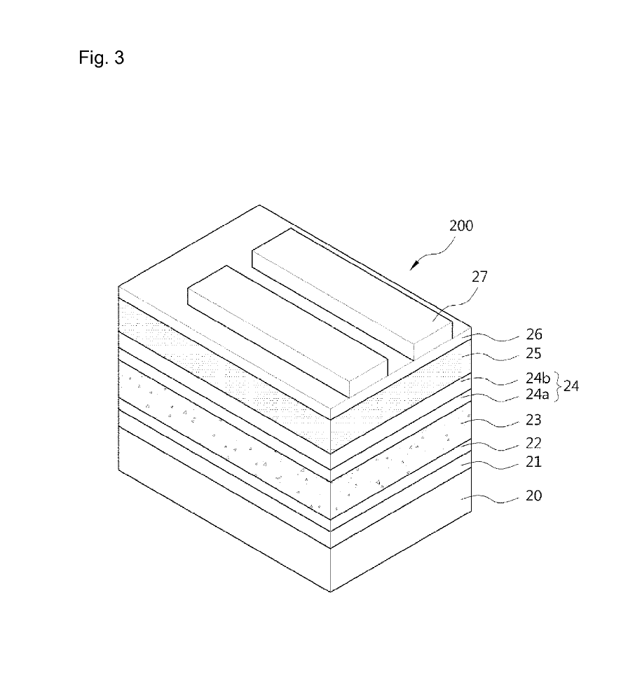

FIG. 3 is a schematic view of a tandem organic solar cell 200 according to one exemplary embodiment of the present invention.

Referring to FIG. 3, a first electrode 21, a first charge transport layer 22, a first organic photoactive layer 23, a recombination layer 24, a second organic photoactive layer 25, a second charge transport layer 26 and a second electrode 27 may be sequentially formed on a substrate 20.

The substrate 20, the first electrode 21, the first organic photoactive layer 23, and the second organic photoactive layer 25 are similar to the substrate 10, the first electrode 21, the first organic photoactive layer 23, and the second organic photoactive layer 25 of the organic solar cell described with reference to FIG. 1, respectively.

The first charge transport layer 22 may be an electron transport layer for facilitating transport of electrons generated in the first photoactive layer 23 to the first electrode 21. In addition, the first charge transport layer 22 may act as a buffer layer which relieves surface roughness of the first electrode 21. One example of the first charge transport layer 22 may be a titanium oxide layer. The titanium oxide layer may be formed by a sol-gel process and may have a thickness of 2 to 50 nm.

The recombination layer 24 is a layer in which holes generated in the first organic photoactive layer 23 and electrons generated in the second organic photoactive layer 25 recombine each other. The recombination layer 24 may include a conjugated polyelectrolyte layer 24a near the first organic photoactive layer 23 and an n-type semiconductor material layer 24b near the second organic photoactive layer 25.

The conjugated polyelectrolyte layer 24a includes a conjugated polymer having side chain charges and counter ions having charges opposite the charges of the conjugated polymer to exhibit electrolyte characteristics. The conjugated polyelectrolyte layer 24a, particularly, the main chain of the polyelectrolyte, may have a lower LUMO energy level than that of the first organic photoactive layer 23 (in view of vacuum level). Consequently, the conjugated polyelectrolyte layer 24a is capable of suppressing inflow of the electrons from the first organic photoactive layer 23. On the other hand, an electric field of a part near the conjugated polyelectrolyte layer 24a becomes different from the electric field of the overall cell elements through movement of ions in the conjugated polyelectrolyte layer 24a, thereby allowing the holes in the first organic photoactive layer 23 to be easily transferred to the conjugated polyelectrolyte layer 24a by increased intensity of the electric field. In this case, limitation to the energy level of the HOMO in the conjugated polyelectrolyte layer 24a may be relieved.

A detailed description of materials for the conjugated polyelectrolyte layer 24a, that is, conjugated polyelectrolyte, is provided in the above description of the embodiment with reference to FIG. 1.

The n-type semiconductor material layer 24b facilitates inflow of the electrons from the second organic photoactive layer 25 but suppresses inflow of the holes therefrom. In the n-type semiconductor material layer 24b, an energy level of the LUMO (Lowest Unoccupied Molecular Orbital) or the conduction band may be higher than that of the LUMO in the second organic photoactive layer 25 (in view of vacuum level), and an energy level of the HOMO (Highest Occupied Molecular Orbital) or the valence band may be higher than that of the HOMO in the second organic photoactive layer 25 (in view of vacuum level). The n-type semiconductor material layer 24b may be a metal oxide layer. The metal oxide may be titanium oxide, zinc oxide, tungsten oxide, vanadium oxide, molybdenum oxide, or combinations thereof.

The LUMO of the conjugated polyelectrolyte layer 24a has a lower energy level than the LUMO of the n-type semiconductor material layer 24b (in view of vacuum level), so that the electrons introduced into the n-type semiconductor material layer 24b are blocked by the energy level of the LUMO in the conjugated polyelectrolyte layer 24a and thus cannot drift to thereto. Further, since the HOMO of the n-type semiconductor material layer 24b has a higher energy level than the HOMO of the conjugated polyelectrolyte layer 24a (in view of energy level under vacuum), the holes introduced into the conjugated polyelectrolyte layer 24a are blocked by the energy level of the HOMO in the n-type semiconductor material layer 24b and thus cannot drift to thereto. Therefore, the holes and the electrons may recombine each other at an interface between the n-type semiconductor material layer 24b and the conjugated polyelectrolyte layer 24a.

The second charge transport layer 26 may act as a hole transport layer which facilitates transport of holes from the second organic photoactive layer 25 to the second electrode 27. One example of the second charge transport layer 26 includes a layer which contains PEDOT:PSS (poly(3,4-ethylenedioxythiophene):poly(styrenesulfonate)) or the conjugated polyelectrolyte described below.

The second electrode 27 has a higher work function than the first electrode 21 (in view of energy level under vacuum). For example, the second electrode 27 may be an Au layer, but is not limited thereto. If the second charge transport layer is formed of PEDOT:PSS (poly(3,4-ethylenedioxythiophene):poly(styrenesulfonate)) or the aforementioned conjugated polyelectrolyte, both of which are conductive layers having higher work functions than the first electrode 21, the second electrode 27 may be formed of a material, for example Al, which has the same or lower work function than the first electrode 21 (in view of vacuum level).

The second electrode 27 may be formed by thermal evaporation, e-beam evaporation, RF sputtering or magnetron sputtering, without being limited thereto.

The tandem organic solar cell according to this embodiment may be subjected to heat treatment. The heat treatment may be performed at 80° C. to 200° C., preferably 150° C.

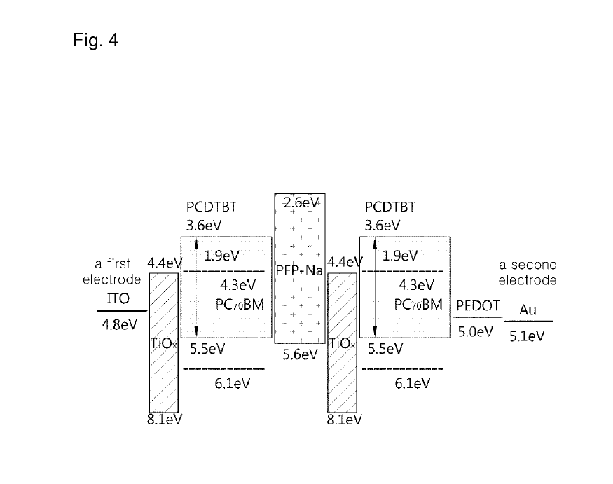

FIG. 4 is an energy diagram of one example of the tandem organic solar cell of FIG. 3. Specifically, the first electrode 21 (in FIG. 3) is an ITO layer and the first charge transport layer 22 (in FIG. 3) is a TiOx layer. Each of the first and second organic photoactive layers 23, 25 (in FIG. 3) is a PCDTBT:PC₇₀BM layer and the recombination layer 24 (in FIG. 3) includes a PFP-Na layer and a TiOx layer sequentially stacked on the first organic photoactive layer 23 (in FIG. 3). The second charge transport layer 26 (in FIG. 3) is a PEDOT:PSS layer and the second electrode 27 (in FIG. 3) is an Au layer.

Referring to FIG. 4, the LUMO of the conjugated polyelectrolyte layer (PFP-Na layer) has an energy level of 2.6 eV, which is greater than an energy level of 4.3 eV of the LUMO of PC₇₀BM used as the electron acceptor material and an energy level of 3.6 eV of the LUMO of PCDTBT used as the electron donor material in the first organic photoactive layer (PCDTBT:PC₇₀BM). As a result, the conjugated polyelectrolyte layer may suppress inflow of electrons from the first organic photoactive layer (PCDTBT:PC₇₀BM). On the other hand, the HOMO of the conjugated polyelectrolyte layer (PFP-Na layer) has an energy level of 5.6 eV, which is greater than an energy level of 5.5 eV of the HOMO of PCDTBT used as the electron donor material in the first organic photoactive layer (PCDTBT:PC₇₀BM). Although such a difference in HOMO energy levels can obstruct inflow of holes from the first organic photoactive layer (PCDTBT:PC₇₀BM) into the conjugated polyelectrolyte layer, variation in intensity of the electric field through rearrangement of ions in the conjugated polyelectrolyte layer (PFP-Na layer) may result in efficient inflow of the holes from the first organic photoactive layer (PCDTBT:PC₇₀BM).

The conduction band of the n-type semiconductor material layer (titanium oxide layer) has an energy level of 4.4 eV, which is greater than an energy level of 4.3 eV of the LUMO of PC₇₀BM used as the electron acceptor material and an energy level of 3.6 eV of the LUMO of PCDTBT used as the electron donor material in the second organic photoactive layer (PCDTBT:PC₇₀BM). Further, the valence band of the of the n-type semiconductor material layer (titanium oxide layer) has an energy level of 8.1 eV, which is greater than an energy level of 5.5 eV of the HOMO of PCDTBT used as the electron donor material in the second organic photoactive layer (PCDTBT:PC₇₀BM). Accordingly, the n-type semiconductor material layer (titanium oxide layer) may facilitate inflow of electrons from the second organic photoactive layer (PCDTBT:PC70BM) while suppressing inflow of holes therefrom.

Further, the electrons introduced into the n-type semiconductor material layer (titanium oxide layer) are blocked by the energy level of the LUMO in the conjugated polyelectrolyte layer (PFP-Na layer) and thus cannot further drift thereto. The holes introduced into the conjugated polyelectrolyte layer (PFP-Na layer) are blocked by the energy level of the HOMO in n-type semiconductor material layer (titanium oxide layer) and thus cannot drift to thereto. As a result, the holes and the electrons may recombine each other at an interface between the n-type semiconductor material layer (titanium oxide layer) and the conjugated polyelectrolyte layer (PFP-Na layer).

Next, the present invention will be described in detail with reference to illustrative examples. However, it should be understood that the following examples are presented to further illustrate the invention and are not construed as limiting the invention.

### Example 1

### Preparation of Tandem Organic Solar Cell

A substrate was prepared by coating an ITO layer as a first electrode on a glass substrate. PEDOT:PSS was coated to a thickness of 30 mm on the ITO layer to form a first charge transport layer. As an electron donor material and an electron acceptor material, PCDTBT and PC70BM were blended in dichlorobenzene to prepare a PCDTBT:PC₇₀BM solution, which in turn was coated to a thickness of 80 nm by spin coating, thereby forming a first organic photoactive layer.

Ti precursor sol was prepared in a nitrogen atmosphere using Ti(IV) isopropanol, 2-methoxyethanol and ethanolamine, and was then coated on the first organic photoactive layer by spin coating. The coated Ti precursor sol formed a titanium oxide layer, that is, an n-type semiconductor material layer, through sol-gel reaction.

PFP-Na as a conjugated polyelectrolyte was dissolved in a solvent prepared by blending 40 wt % of methanol, 40 wt % of isopropanol, and 20 wt % of water to prepare a conjugated polyelectrolyte solution, which in turn was coated to a thickness of 25 nm on the n-type semiconductor layer by spin coating, thereby forming a conjugated polyelectrolyte layer.

Then, the PCDTBT:PC70BM solution was coated to a thickness of 80 nm on the conjugated polyelectrolyte layer by spin coating, thereby forming a second organic photoactive layer.

The Ti precursor sol was coated on the second organic photoactive layer by spin coating. The coated Ti precursor sol formed a titanium oxide layer, that is, a second charge transport layer, through sol-gel reaction.

Then, Al was finally deposited on the second charge transport layer to form a second electrode.

### Comparative Example 1

### Preparation of Monolayer Organic Solar Cell

In Comparative Example 1, the process of forming an n-type semiconductor material layer, the process of forming a conjugated polyelectrolyte layer, and the process of forming a second organic photoactive layer of Example 1 were omitted. Instead, a titanium oxide layer was formed on the first organic photoactive layer, followed by depositing a second electrode on the titanium oxide layer to prepare a monolayer organic solar cell.

### Comparative Example 2

A tandem organic solar cell of Comparative Example 2 was prepared by the same method as in Example 1, except that, instead of the conjugated polyelectrolyte layer, PEDOT:PSS (Clevios PH500, H.C. Starck, Inc.) was coated on the n-type semiconductor material layer to form a conductive layer.

### Comparative Example 3

The tandem organic solar cell prepared in Comparative Example 2 was subjected to heat treatment at 150° C. for 10 minutes.

Property of Organic Solar Cell

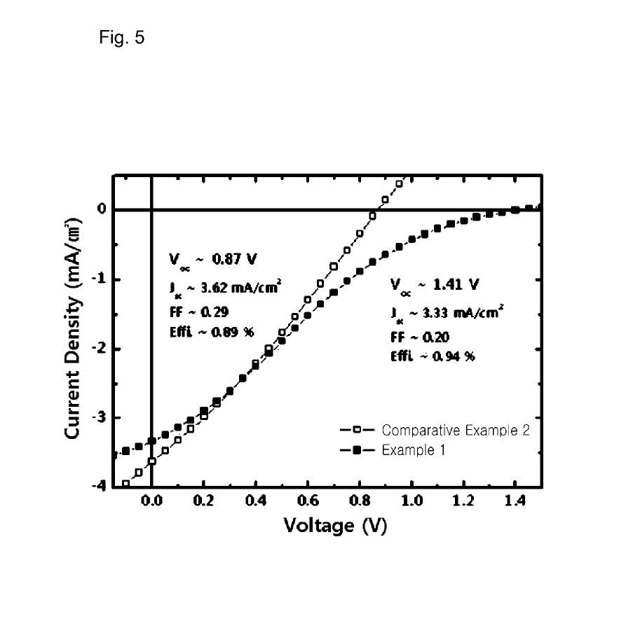

Table 1 shows open circuit voltages of the solar cells prepared in Comparative Examples 1 and 2 and Example 1, and FIG. 5 is a graph depicting current density with respect to voltage of tandem organic solar cells prepared in Example 1 and Comparative Example 2.

TABLE 1

| | | Recombination | Heat | Voc |
|---|---|---|---|---|
| | Kind of solar cell | layer | treatment | (V) |
| Comparative | Single solar cell | No | No | 0.88 |
| Example 1 | | | | |
| Comparative | Tandem solar cell | Ti oxide | No | 0.87 |
| Example 2 | | layer/PEDOT: PSS | | |
| Comparative | Tandem solar cell | Ti oxide | 150° C. | 1.34 |
| Example 3 | | layer/PEDOT: PSS | for 10 | |
| | | | minute | |
| Example 1 | Tandem solar cell | Ti oxide layer/ | No | 1.41 |
| | | PFF-Na | | |

Referring to Table 1 and FIG. 5, the tandem organic solar cell of Comparative Example 2, which includes the recombination layer consisting of the n-type semiconductor layer and the conductive layer (PEDOT:PSS), was not subjected to heat treatment and had an open circuit voltage of 0.87V, which was similar to that of the single organic solar cell of Comparative Example 1. Consequently, it could be seen that the solar cell of Comparative Example 2 was not operated as a tandem solar cell. Additionally, the tandem organic solar cell subjected to heat treatment (Comparative Example 3) had an open circuit voltage of 1.34V, which was lower than the open circuit voltage of the solar cell of Example 1.

On the contrary, the solar cell of Example 1, which includes the recombination layer consisting of the n-type semiconductor layer and the conjugated polyelectrolyte layer (PFP-Na), had an open circuit voltage of 1.41V even without heat treatment. This open circuit voltage is about two times that of the monolayer solar cell of Comparative Example 1. Consequently, it could be seen that the solar cell of Example 1 was operated as a tandem solar cell even without heat treatment.

As such, since a tandem organic solar cell including a recombination layer consisting of an n-type semiconductor layer and a conjugated polyelectrolyte layer exhibits excellent open circuit voltage even without heat treatment, limitation on materials for a photoactive layer of the tandem organic solar cell may be overcome. Generally, considering advantageous characteristics of heat vulnerable polymers, polymer solar cells realized through a room temperature solution process will be used as inexpensive next generation energy sources.

Although some embodiments have been described herein, it should be understood by those skilled in the art that these embodiments are given by way of illustration only, and that various modifications, variations, and alterations can be made without departing from the spirit and scope of the invention. Therefore, the scope of the invention should be limited only by the accompanying claims and equivalents thereof.

1. A tandem organic solar cell comprising:
a first electrode;
a first organic photoactive layer formed on the first electrode;
a recombination layer formed on the first organic photoactive layer, the recombination layer comprising an n-type semiconductor material layer and a conjugated polyelectrolyte layer;
a second organic photoactive layer formed on the recombination layer; and
a second electrode formed on the second organic photoactive layer.

2. The tandem organic solar cell of claim 1, wherein the conjugated polyelectrolyte layer contains at least one selected from the group consisting of poly(9,9-bis(6″-(N,N,N-trimethylammonium)hexyl)fluorene-alt-co-phenylene), poly((2-cyclooctatetraenylethyl)-trimethylammonium trifluoromethanesulfonate), poly-(tetramethylammonium-2-cyclooctatetraenylethanesulfonate), poly((2-methoxy-5-(3-sulfonatopropoxy)-1,4-phenylene)-1,2-ethenediyl), poly((2-methoxy-5-propyloxysulfonate-1,4-phenylenevinylene)-alt-(1,4-phenylenevinylene)), sulfonated poly(p-phenylene), sulfonated poly(phenylene ethynylene), poly(carboxylatedphenylene ethynylene), poly(N-(4-sulfonatobutyloxyphenyl)-4,4′-diphenylamine-alt-1,4-phenylene), poly(N-4,4′-diphenylamine-alt-N-(p-trifluoromethyl)phenyl-4,4′-diphenylamine), poly((9,9-bis(6′-(N,N,N-trimethylammonium)hexyl)-fluorene-2,7-diyl)-alt-(2,5-bis(pphenylene)-1,3,4-oxadiazole)), poly((9,9-bis(6′-N,N,N-trimethylammoniumbromide)hexyl)fluorene-co-alt-4,7-(2,1,3-benzothiadiazole)), and PFP(poly(9,9′-bis(4-sulfonatobutyl)fluorene-alt-co-1,4-phenylene)).

3. The tandem organic solar cell of claim 2, wherein the conjugated polyelectrolyte layer contains H, Na, K or tetradecyltrimethylammonium (TDMA) as counter cations, or Br, BF₄, CF₃SO₃, PF₆, BPh₄, and B(3,5-(CF₃)₂C₆H₃)₄(BArF₄) as counter anions.

4. The tandem organic solar cell of claim 2, wherein the conjugated polyelectrolyte layer contains a material represented by Formula 1: 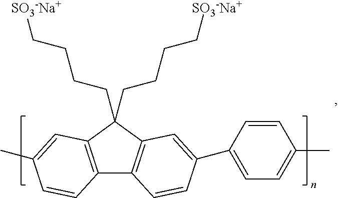
where n may be an integer in the range from 10 to 100000.

5. The tandem organic solar cell of claim 1, wherein the n-type semiconductor material layer is a metal oxide layer.

6. The tandem organic solar cell of claim 5, wherein the metal oxide is titanium oxide, zinc oxide, tungsten oxide, vanadium oxide, or molybdenum oxide.

7. The tandem organic solar cell of claim 1, further comprising: a first charge transport layer formed between the first electrode and the first organic photoactive layer.

8. The tandem organic solar cell of claim 1, further comprising: a second charge transport layer formed between the second organic photoactive layer and the second electrode.

9. A tandem organic solar cell comprising:
a first electrode;
a first organic photoactive layer formed on the first electrode;
a recombination layer comprising an n-type semiconductor material layer and a conjugated polyelectrolyte layer sequentially formed on the first organic photoactive layer;
a second organic photoactive layer formed on the recombination layer; and
a second electrode formed on the second organic photoactive layer.

10. The tandem organic solar cell of claim 9, wherein the second electrode has a lower work function than the first electrode.

11. The tandem organic solar cell of claim 9, further comprising: a charge transport layer formed between the first electrode and the first organic photoactive layer.

12. The tandem organic solar cell of claim 11, wherein the charge transport layer is a PEDOT:PSS layer or a conjugated polyelectrolyte layer.

13. The tandem organic solar cell of claim 9, further comprising: a charge transport layer formed between the second organic photoactive layer and the second electrode.

14. The tandem organic solar cell of claim 13, wherein the charge transport layer is a Ti oxide layer.

15. A tandem organic solar cell comprising:
a first electrode;
a first organic photoactive layer formed on the first electrode;
a recombination layer comprising a conjugated polyelectrolyte layer and an n-type semiconductor material layer sequentially formed on the first organic photoactive layer;
a second organic photoactive layer formed on the recombination layer; and
a second electrode formed on the second organic photoactive layer.

16. The tandem organic solar cell of claim 15, wherein the second electrode has a higher work function than the first electrode.

17. The tandem organic solar cell of claim 15, further comprising: a charge transport layer formed between the first electrode and the first organic photoactive layer.

18. The tandem organic solar cell of claim 17, wherein the charge transport layer is a Ti oxide layer.

19. The tandem organic solar cell of claim 15, further comprising: a charge transport layer formed between the second organic photoactive layer and the second electrode.

20. The tandem organic solar cell of claim 19, wherein the charge transport layer is a PEDOT:PSS layer or a conjugated polyelectrolyte layer.

21. A method for manufacturing a tandem organic solar cell, comprising:
forming a first electrode;
forming a first organic photoactive layer on the first electrode;
forming a recombination layer on the first organic photoactive layer, the recombination layer comprising an n-type semiconductor material layer and a conjugated polyelectrolyte layer;
forming a second organic photoactive layer on the recombination layer; and
forming a second electrode on the second organic photoactive layer.

22. The method of claim 21, wherein the conjugated polyelectrolyte layer contains at least one selected from the group consisting of poly(9,9-bis(6″-(N,N,N-trimethylammonium)hexyl)fluorene-alt-co-phenylene), poly((2-cyclooctatetraenylethyl)-trimethylammonium trifluoromethanesulfonate), poly-(tetramethylammonium-2-cyclooctatetraenylethanesulfonate), poly((2-methoxy-5-(3-sulfonatopropoxy)-1,4-phenylene)-1,2-ethenediyl), poly((2-methoxy-5-propyloxysulfonate-1,4-phenylenevinylene)-alt-(1,4-phenylenevinylene)), sulfonated poly(p-phenylene), sulfonated poly(phenylene ethynylene), poly(carboxylatedphenylene ethynylene), poly(N-(4-sulfonatobutyloxyphenyl)-4,4′-diphenylamine-alt-1,4-phenylene), poly(N-4,4′-diphenylamine-alt-N-(p-trifluoromethyl)phenyl-4,4′-diphenylamine), poly((9,9-bis(6′-(N,N,N-trimethylammonium)hexyl)-fluorene-2,7-diyl)-alt-(2,5-bis(pphenylene)-1,3,4-oxadiazole)), poly((9,9-bis(6′-N,N,N-trimethylammoniumbromide)hexyl)fluorene-co-alt-4,7-(2,1,3-benzothiadiazole)), and PFP(poly(9,9′-bis(4-sulfonatobutyl)fluorene-alt-co-1,4-phenylene)).

23. The method of claim 21, wherein the conjugated polyelectrolyte layer contains H, Na, K or tetradecyltrimethylammonium (TDMA) as counter cations, or Br, BF₄, CF₃SO₃, PF₆, BPh₄, and B(3,5-(CF₃)₂C₆H₃)₄(BArF₄) as counter anions.

24. The method of claim 21, wherein the conjugated polyelectrolyte layer contains a material represented by Formula 1: 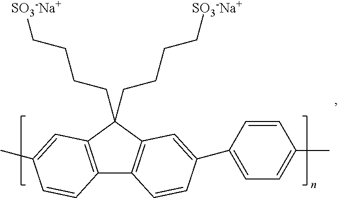
where n may be an integer in the range from 10 to 100000.

25. The method of claim 21, wherein the n-type semiconductor material layer is a metal oxide layer.

26. The method of claim 25, wherein the metal oxide is titanium oxide, zinc oxide, tungsten oxide, vanadium oxide, or molybdenum oxide.

27. The method of claim 21, further comprising: forming a first charge transport layer between the first electrode and the first organic photoactive layer.

28. The method of claim 21, further comprising: forming a second charge transport layer between the second organic photoactive layer and the second electrode.
